(19) United States
(12) Patent Application Publication
(10) Pub. No.: US 2010/0177556 A1
(43) Pub. Date: Jul. 15, 2010

(54) ASYMMETRIC STATIC RANDOM ACCESS MEMORY

(75) Inventors: Jui-Lung Chen, Hsinchu City (TW); Wei-Shung Chen, Hsinchu County (TW); Yi-Hsun Chung, Miaoli County (TW); Chia-Chiuan Chang, Miaoli County (TW)

Correspondence Address: QUINTERO LAW OFFICE, PC, 615 Hampton Dr, Suite A202, Venice, CA, 90291, US

(73) Assignee: VANGUARD INTERNATIONAL SEMICONDUCTOR CORPORATION, Hsinchu (TW)

(21) Appl. No.: 12/351,772

(22) Filed: Jan. 9, 2009

(51) Int. Cl. G11C 11/00; G11C 5/14

(52) U.S. Cl. 365/156; 365/154; 365/226

(57) ABSTRACT

An asymmetric static random access memory (SRAM) device that includes at least one SRAM cell is provided. The SRAM cell includes the first inverter and the second inverter. The first inverter is coupled between a first power and a ground power, and includes a first output terminal coupled to a first node and a first input terminal coupled to a second node. The second inverter is coupled between the first power and the ground power, and includes a second input terminal coupled to the first node and a second output terminal coupled to the second node. When the first inverter and the second inverter receive current from the first power, the SRAM cell is programmed to a predetermined value in advance according to different conductance levels of the first inverter and the second inverter.

### BACKGROUND OF THE INVENTION

1. Field of the Invention

The invention relates to a memory circuit, and more particularly to an asymmetric static random access memory.

2. Description of the Related Art

The types of semiconductor memory devices may be divided into a read-writable memory and a read only memory device. The types of read-writable memory may further divided into a Dynamic Random Access Memory (DRAM) and a Static Random Access Memory (SRAM).

### BRIEF SUMMARY OF THE INVENTION

Static random access memory (SRAM) cells are provided. An exemplary embodiment of an asymmetric static random access memory (SRAM) device comprises at least one SRAM cell. The SRAM cell comprises a first inverter and a second inverter. The first inverter is coupled between a first power and a ground power, and comprises a first output terminal coupled to a first node and a first input terminal coupled to a second node. The second inverter is coupled between the first power and the ground power, and comprises a second input terminal coupled to the first node and a second output terminal coupled to the second node. When the first inverter and the second inverter receive current from the first power, the SRAM cell is programmed to a predetermined value in advance according to different conductance levels of the first inverter and the second inverter.

Another exemplary embodiment of a static random access memory (SRAM) cell comprises a first NMOS transistor having a first threshold voltage and coupled between a first node and a ground power, a first PMOS transistor having a second threshold voltage and coupled between the first node and a first power, a second NMOS transistor having a third threshold voltage and coupled between a second node and the ground power, and a second PMOS transistor having a fourth threshold voltage and coupled between the second node and the first power, wherein the first NMOS, the first PMOS, the second NMOS and the second PMOS transistors conduct with different conductance levels due to the first, the second, the third and the fourth threshold voltages so that the SRAM cell is programmed to a predetermined value in advance.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a six transistors (6T) asymmetric Static Random Access Memory according to an embodiment of the invention;

FIG. 2 shows a transfer curve diagram of the asymmetric SRAM;

FIG. 3 shows a memory cell power circuit according to an embodiment of the invention; and

FIG. 4 shows the power supply order according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Besides the Arithmetic Logic Unit (ALU), the Micro Control Unit (MCU) further comprises an SRAM for performing operations and a Read Only Memory (ROM) for storing the commands for a powering on process. When the power on process of an apparatus is activated, the POWER ON RESET circuit initiates the setting of the MCU to an initial state, and then reads the power on commands from an initial position and downloads the daemon programs to the SRAM. Since the ROM and SRAM individually occupy a portion of memory addresses, and the power on commands are no longer used after being read during the power on process, and further, some daemon programs may need to be downloaded to the host memory during the power on process, the time during the power on process may be long and power consumption during the power on process may be high. Thus, a novel SRAM cell is needed for mitigate the described problems.

According to an embodiment of the invention, the threshold voltages of the transistors in an SRAM device are adjusted by using an adjustable ion implantation layer (will be discussed in detail later), so as to change the symmetry of the SRAM. In this way, when the power is input, the status of the memory device is adjusted to a predetermined state. In addition, since the threshold voltages are slightly changed, the programmed memory cells may still keep the original SRAM properties and still able to be written with data.

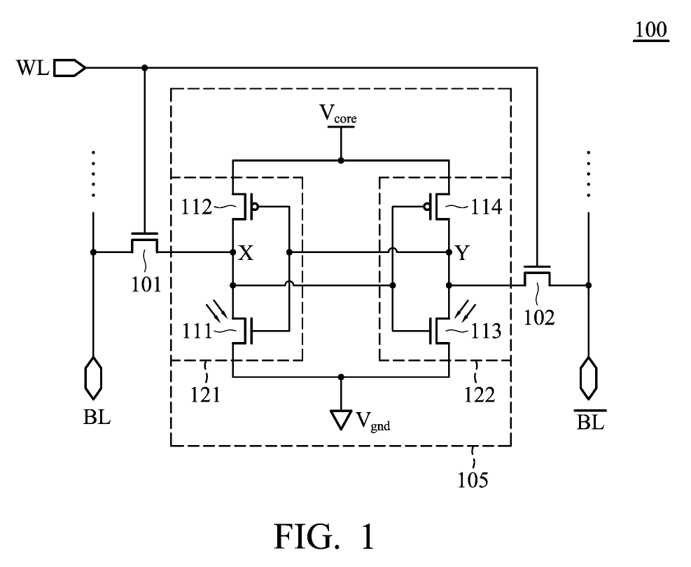

FIG. 1 shows a six transistors (6T) asymmetric Static Random Access Memory (SRAM) 100. An asymmetric SRAM 100 comprises switches 101 and 102, and at least one memory cell 105. According to an embodiment of the invention, the switches 101 and 102 are NMOS transistors. However, it is to be noted that the switches 101 and 102 may also be implemented by other devices and the invention should not be limited thereto. The memory cell 105 is a latch circuit with two cross-coupled inverters. The first inverter 121 comprises a NMOS transistor 111 and a PMOS transistor 112. The second inverter 122 comprises a NMOS transistor 113 and a PMOS transistor 114. Nodes X and Y are complementary and used for storing digital data. The asymmetric SRAM 100 accesses data via the word line WL and bit lines BL and B̅L̅ of peripheral devices (not shown).

For storing data, as an example, when the asymmetric SRAM 100 is written by ‘1’, the voltage at the bit line BL is pulled up to V_{dd}, and the voltage at the bit line B̅L̅ is pulled down to the ground voltage V_{gnd}. The word line WL turns on the NMOS transistors 101 and 102, and thus the voltage at the node X is high and the voltage at the node Y is low. When the asymmetric SRAM 100 is written by ‘0’, the voltage at the bit line BL is pulled down to ground voltage V_{gnd} and the voltage at the bit line B̅L̅ is pulled up to V_{dd}. The word line WL turns on the NMOS transistors 101 and 102, and thus the voltage at the node X is at a low voltage level and the voltage at the node Y is at a high voltage level.

For reading data, as an example, when the data ‘1’ stored in the memory cell 105 is to be read, the voltage at the bit line BL is charged to V_{dd} in advance and the voltage at the bit line B̅L̅ is pulled down to V_{gnd} in advance. Next, the NMOS transistors 101 and 102 are turned on by the word line WL. Next, the system detects the voltages at bit lines BL and B̅L̅. Since the node X is at a high voltage level and node Y is at a low voltage level, the voltage at the bit line BL will not be pulled down and the voltage at the bit line B̅L̅ will not be pulled up. Thus, the stored ‘1’ in the memory cell 105 may be known by the system.

When the data ‘0’ stored in the memory cell 105 is to be read, the voltage at the bit line BL is charged to V_{dd} in advance and the voltage at the bit line B̅L̅ is pulled down to V_{gnd} in advance. Next, the NMOS transistors 101 and 102 are turned on by the word line WL. Next, the system detects the voltages at bit lines BL and B̅L̅. Since the node X is at a low voltage level and node Y is at a high voltage level, the voltage at the bit line BL is pulled down and the voltage at the bit line B̅L̅ is pulled up. Thus, the stored ‘0’ in the memory cell 105 may be known by the system.

According to an embodiment of the invention, the NMOS transistors 111 and 113 have different threshold voltages. The threshold voltage of the NMOS transistor 113 is raised up by 0.2V so that the threshold voltage VT₁₁₃ of the NMOS transistor 113 is 0.2V higher than the threshold voltage VT₁₁₁ of the NMOS transistor 111. Thus, when the power is input to the asymmetric SRAM 100, the memory cell 105 is programmed in advance. Since the NMOS transistor 111 is turned on earlier, the voltage at the node X is pulled down and the voltage at the node Y is pulled up so that the memory cell 105 is programmed to ‘0’ in advance. It is to be noted that it is also applicable to adjust the threshold voltage of other transistors 111, 112, 114 or any combination thereof and the invention should not be limited thereto. As an example, the threshold voltage of the NMOS transistor 113 is raised up by 0.1V and the threshold voltage of the PMOS transistor 114 is lowered by 0.1V.

According to another embodiment of the invention, the threshold voltage of NMOS transistor 111 is raised up by 0.2V so that the threshold voltage VT₁₁₁ of the NMOS transistor 111 is 0.2V higher than the threshold voltage VT₁₁₃ of the NMOS transistor 113. Thus, when the power is input to the asymmetric SRAM 100, the memory cell 105 is programmed in advance. Since the NMOS transistor 113 is turned on earlier, the voltage at the node Y is pulled down and the voltage at the node X is pulled up so that the memory cell 105 is programmed to ‘1’ in advance. Thus, the memory cell 105 may be programmed to a predetermined value ‘0’ or ‘1’ in advance.

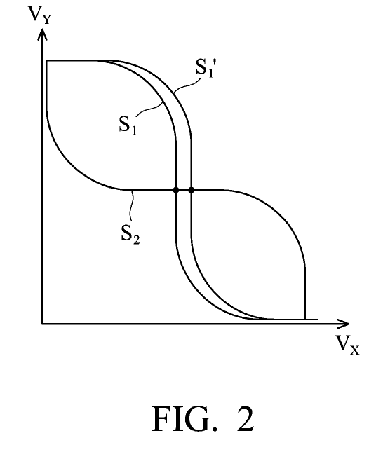

FIG. 2 shows a transfer curve diagram of the asymmetric SRAM 100. The curve SI represents the transfer curve of the second inverter 122 and the curve S2 represents the transfer curve of the first inverter 121. The curve S1′ represents the transfer curve of the second inverter 122 when the threshold voltage of NMOS transistor 113 is raised up by 0.2V. The horizontal axis represents the voltage at the node X and the vertical axis represents the voltage at the node Y.

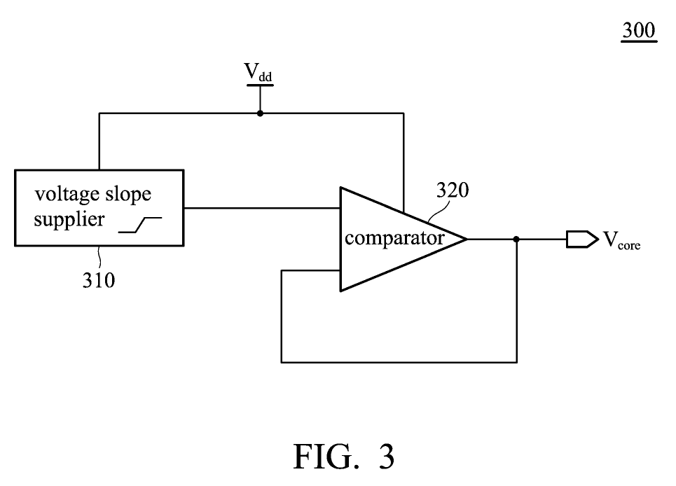

FIG. 3 shows a memory cell power circuit 300 according to an embodiment of the invention. The memory cell power circuit 300 comprises a voltage slope supplier 310 and a comparator 320. The memory cell power circuit 300 provides a core power V_{core} with a predetermined slope. Since the peripheral circuits should be started up first so that the word line WL may turn off the switches 101 and 102 to prevent the bit lines BL and B̅L̅ from affecting the memory cell 105, the start up order is (1) peripheral circuits, and next (2) the memory cell power circuit 300, and finally (3) the memory cell 105. As shown in FIG. 3, the memory cell power circuit 300 provides another core power V_{core} to the memory cell 105 according to the voltage level of power Vdd.

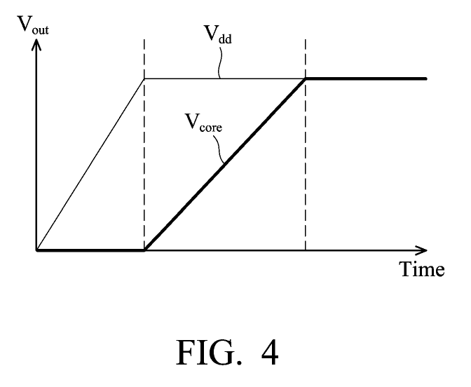

FIG. 4 is a diagram showing the power supply order according to an embodiment of the invention. As shown in FIG. 4, the voltage level of the power V_{dd} is pulled up earlier than the core power V_{core}. The peripheral circuits receive the power V_{dd} first, and then the memory cell receives the core power V_{core}. Thus, the peripheral circuits are started up prior to the memory cell, where the memory cell power circuit 300 as shown in FIG. 3 controls the slope of the core power V_{core}.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. An asymmetric static random access memory (SRAM) device, comprising at least one SRAM cell, wherein the SRAM cell comprises:
a first inverter coupled between a first power and a ground power, and comprising a first output terminal coupled to a first node and a first input terminal coupled to a second node; and
a second inverter coupled between the first power and the ground power, and comprising a second input terminal coupled to the first node and a second output terminal coupled to the second node,
wherein when the first inverter and the second inverter receive current from the first power, the SRAM cell is programmed to a predetermined value in advance according to different conductance levels of the first inverter and the second inverter.

2. The asymmetric SRAM device as claimed in claim 1, wherein the first inverter comprises:
a first NMOS transistor having a first threshold voltage and coupled between the first node and the ground power; and
a first PMOS transistor having a second threshold voltage and coupled between the first node and the first power.

3. The asymmetric SRAM device as claimed in claim 2, wherein the first inverter comprises:
a second NMOS transistor having a third threshold voltage and coupled between the second node and the ground power; and
a second PMOS transistor having a fourth threshold voltage and coupled between the second node and the first power.

4. The asymmetric SRAM device as claimed in claim 3, wherein the first inverter and the second inverter conduct differently due to the first, the second, the third and the fourth threshold voltages so that the SRAM cell is programmed to the predetermined value in advance.

5. The asymmetric SRAM device as claimed in claim 3, wherein the fourth threshold voltage equals to the third threshold voltage, and the first threshold voltage does not equal to the third threshold voltage.

6. The asymmetric SRAM device as claimed in claim 3, wherein when the first threshold voltage is higher or lower than the third threshold voltage, the SRAM cell is programmed to the predetermined value in advance.

7. The asymmetric SRAM device as claimed in claim 3, wherein the fourth threshold voltage does not equal to the third threshold voltage, and the first threshold voltage equals to the third threshold voltage.

8. The asymmetric SRAM device as claimed in claim 7, wherein when the second threshold voltage is higher or lower than the fourth threshold voltage, the SRAM cell is programmed to the predetermined value in advance.

9. The asymmetric SRAM device as claimed in claim 3, wherein the first threshold voltage, the second threshold voltage, the third threshold voltage and the fourth threshold voltage are respectively controlled by adjusting an ion implantation layer of the first NMOS transistor, the first PMOS transistor, the second NMOS transistor and the second PMOS transistor.

10. The asymmetric SRAM device as claimed in claim 3, further comprising:
a first switch transmitting a signal on a bit line to the first node according to conductance of a word line; and
a second switch transmitting a signal on a complementary bit line to the second node according to the conductance of the word line.

11. A static random access memory (SRAM) cell, comprising:
a first NMOS transistor having a first threshold voltage and coupled between a first node and a ground power;
a first PMOS transistor having a second threshold voltage and coupled between the first node and a first power;
a second NMOS transistor having a third threshold voltage and coupled between a second node and the ground power; and
a second PMOS transistor having a fourth threshold voltage and coupled between the second node and the first power,
wherein the first NMOS, the first PMOS, the second NMOS and the second PMOS transistors conduct with different conductance levels due to the first, the second, the third and the fourth threshold voltages so that the SRAM cell is programmed to a predetermined value in advance.

12. The SRAM cell as claimed in claim 11, wherein when the first threshold voltage is higher or lower than the third threshold voltage, the SRAM cell is programmed to the predetermined value in advance.

13. The SRAM cell as claimed in claim 11, when the second threshold voltage is higher or lower than the fourth threshold voltage, the SRAM cell is programmed to the predetermined value in advance.

14. The SRAM cell as claimed in claim 11, wherein the first threshold voltage, the second threshold voltage, the third threshold voltage and the fourth threshold voltage are respectively controlled by adjusting an ion implantation layer of the first NMOS transistor, the first PMOS transistor, the second NMOS transistor and the second PMOS transistor.
